(19) United States
(12) Patent Application Publication
(10) Pub. No.: US 2021/0395883 A1
(43) Pub. Date: Dec. 23, 2021

(54) System and Method for Thermally Cracking Ammonia

(71) Applicant: Tokyo Electron Limited, Tokyo (JP)

(72) Inventor: Anthony Dip, Cedar Creek, TX (US)

(21) Appl. No.: 17/316,338

(22) Filed: May 10, 2021

Related U.S. Application Data
(60) Provisional application No. 63/042,162, filed on Jun. 22, 2020.

(51) Int. Cl. C23C 16/34; C23C 16/452

(52) U.S. Cl. CPC C23C 16/345; C23C 16/347; C23C 16/452

(57) ABSTRACT

Systems and methods are provided herein to thermally activate a nitrogen-containing gas at lower activation temperatures (e.g., below 2000 C) than conventional hot-wire heating methods, while more effectively heating larger gas volumes. In the disclosed embodiments, a gas activation chamber is provided within a deposition system for thermally activating a nitrogen-containing gas. In one example, ammonia (NH₃) may be thermally activated within the gas activation chamber to generate ammonia radicals and/or hydrazine compounds before the ammonia, ammonia radicals and/or hydrazine compounds are delivered to the substrate surface. Because ammonia radicals and hydrazine compounds are significantly more reactive than ammonia, especially at lower substrate temperatures (e.g., <900 C), ammonia radicals and hydrazine compounds can be more effectively used to deposit nitride layers (such as silicon nitride) over a broader range of substrate temperatures.

### CROSS-REFERENCE TO RELATED APPLICATIONS

This application claims the benefit of U.S. Provisional Application No. 63/042,162, filed on Jun. 22, 2020, which application is hereby incorporated herein by reference.

### TECHNICAL FIELD

The present disclosure relates to the processing of substrates. In particular, it provides an apparatus and method for treating surfaces of substrates.

### BACKGROUND

Atomic layer deposition (ALD) is a known technique for forming layers on a substrate. In atomic layer deposition, substrates are cyclically exposed to alternate gaseous species (or precursors). The gaseous species react with the substrate surface in a self-limiting or near self-limiting manner. A thin film may be slowly formed by repeating the cycles of alternating gaseous species.

A variety of process tools may be utilized in atomic layer deposition processes. For example, batch furnace type systems may be utilized. Single substrate systems in which a process chamber is filled with gas and evacuated for a single substrate may also be utilized. Yet another system is a spatial ALD system. In spatial ALD systems, substrates travel at relatively high speeds past a plurality of gas sources (e.g., gas injectors, a gas showerhead, or a gas showerhead with injector outlets), which inject the necessary gases proximate the substrate surface to accomplish the ALD process steps as the substrate rotates in a cyclical manner.

Spatial ALD relies on rapid movement of the substrate between alternating gas streams that are isolated from one another. For example, one exemplary spatial ALD process for forming silicon nitride (SiN) may sequentially expose the substrate surface to a silicon-containing precursor gas (such as, e.g., dichlorosilane (DCS)) followed by exposure of the substrate surface to a nitrogen-containing precursor gas (such as, e.g., ammonia, NH₃). In a spatial ALD system, the substrate is often rotated between the NH₃ and DCS precursor gases in rapid succession to build up alternate layers of silicon (Si) and then converting the silicon to silicon nitride (SiN) through exposure to NH₃ until a target thickness is achieved. To avoid gas mixing, the precursor gas streams (DCS, NH₃) are typically separated by physical barriers, purge sources or a combination of the two.

FIG. 1 illustrates one example of a conventional spatial ALD system that may be used to achieve an atomic layer deposition process. More specifically, FIG. 1 provides a top-down view of a substrate process tool 100 (i.e., a spatial ALD system) as seen inside a process chamber 105 of the substrate process tool 100. As shown in FIG. 1, a platen 110 is provided within the process chamber 105 for holding one or more substrates 115. Each of the substrates 115 may be arranged on a susceptor (112, FIG. 2), which supplies heat to the substrate. A number of showerheads and purge blocks may also be provided within the process chamber 105 and located above the platen no for providing various gases to the substrate. Gas outlet pumping ports 130 may also be provided.

In the spatial ALD system shown in FIG. 1, a first showerhead 120 is located above the platen no for providing a first precursor gas (e.g., DCS) to the one or more substrates 115, and a second showerhead 125 is located above the platen 110 for providing a second precursor gas (e.g., ammonia, NH₃) to the one or more substrates 115. As the platen 110 rotates (as indicated by the arrows), the one or more of substrates 115 are moved in sequence under the first showerhead 120 and then under the second showerhead 125 to perform one cycle of the atomic layer deposition process. Purge blocks 128 provide a gas purge (e.g., an argon, nitrogen, or other inert gas purge) after the substrates 115 rotate past each of the showerheads to prevent the precursor gases from mixing. The rotation of the platen 110 and the substrates 115 may be repeated for a number of ALD cycles. Although not shown in FIG. 1, a controller may be provided for controlling various operating parameters of the spatial ALD system including, for example, temperatures, gas flows, pressures, rotation speeds, number of ALD cycles, etc. It will be recognized that the gases, precursors and layers being formed as described herein are merely exemplary and gases, precursors and layers are well-known in the art.

Ammonia (NH₃) is a nitrogen-containing precursor gas that is commonly used for silicon nitride deposition. In addition to ALD, ammonia is widely used in chemical vapor deposition (CVD) processes, since it is generally effective as a nitridizing agent and is relatively safe and stable. However, there are also limitations to using ammonia for the deposition of silicon nitride.

One limiting factor for the deposition of silicon nitride is the processing temperature or thermal budget of the subsequently formed device. Some devices, such as non-volatile memory (NVM) devices, cannot be processed at high temperatures (e.g., >600 C). However, the reaction speed of ammonia tends to drop dramatically as the temperature is reduced. At temperatures below 600 C, silicon nitride ALD processes require extended exposure times to the ammonia, due to reduced reaction speed and a slowdown in the surface kinetics. Temperatures below 600 C may also result in greater impurity content within the deposited film. Impurities typically come from precursors gases, which may have hydrogen (H), chlorine (Cl) and/or carbon (C) as part of the ligand structure. These ligands may not be easily eliminated from the film at low temperatures (e.g., >600 C), and may be incorporated within the film layers as the film layers build up.

As temperatures drop below 400 C, ammonia generally becomes ineffective, and plasma deposition processes must be used to generate the ammonia radicals needed to boost surface reactivity. However, plasma is not always ideal, as thin nitride dielectric films can suffer from charge damage. Like chemical vapor deposition (CVD) processes, plasma does not penetrate well into deep structures, such as those found in three-dimensional (3D) NVM devices. Thus, ALD is often preferred when the device structure is challenging, and when CVD and plasma processes cannot be used due to poor coverage (e.g., uneven film thickness) on many micrometer (um) deep structures with aspect ratios in the 10 um to over 100 (um) range.

Another limiting factor for the deposition of silicon nitride is exposure time. This is more critical for SiN ALD processes, whereby the substrate is sequentially exposed in time to a silicon-containing precursor gas (e.g., DCS) followed by a nitrogen-containing precursor gas (e.g., NH₃). SiN ALD processes are typically performed at temperatures below the decomposition point of the silicon precursor to avoid a CVD component from forming on a structure near the substrate surface. Since the substrate temperature is limited by the silicon precursor, additional exposure time to ammonia is often required to gain the same effect, as would otherwise be achieved at higher temperatures and shorter exposure time.

Thermally activating ammonia to produce radicals is a known process that results in the auto-pyrolytic decomposition of ammonia into several species, such as H₂, N₂, NH₂, NH, N₂H₃, etc. The radical forms of ammonia (i.e., NₓH_{y}, where x,y=0 to 2), and the formation of various hydrazine compounds, are desirable since they have a significantly greater (e.g., 10² to 10⁴ times greater) surface reactivity than ammonia. This is an important characteristic, as the deposition rate of silicon nitride can be accelerated with the use of ammonia radicals. Since radical forms of ammonia are significantly more reactive, they are also more effective in removing undesired chemical species within the deposited film. For example, impurities such as chlorine and hydrogen can be more effectively removed, for a given process condition, when ammonia radicals are employed. The hydrazine compounds formed from ammonia radicals are also many times more reactive than ammonia itself, and thus, are more effective at lower temperatures than ammonia itself.

One known method for thermally activating ammonia is to use metal wire (e.g., tungsten) heating elements in contact with the ammonia at temperatures in excess of 2500 C This hot-wire method suffers from several disadvantages and limitations. As the wire temperature increases above 2000 C, thermoelectric discharge of electrons may occur and result in charging of the substrate. To prevent substrate charging, temperatures should be limited below 2000 C. However, this places limitations on the total volume of gas that can be processed by the metal wire heating elements. Thin wire filaments (e.g., on the order of 0.5 mm in diameter) are generally ineffective in heating large volumes of gas. While additional filaments may be added to increase the heating effectiveness of larger gas volumes, the complexity of managing such filaments over large areas is a complex problem.

### SUMMARY

Systems and methods are provided herein to thermally activate a nitrogen-containing gas at lower activation temperatures (e.g., below 2000 C) than conventional hot-wire heating methods, while more effectively heating larger gas volumes. In the disclosed embodiments, a gas activation chamber is provided within a deposition system for thermally activating a nitrogen-containing gas. In one example, ammonia (NH₃) may be thermally activated within the gas activation chamber to generate ammonia radicals and/or hydrazine compounds before the ammonia, ammonia radicals and/or hydrazine compounds are delivered to the substrate surface. Because ammonia radicals and hydrazine compounds are significantly more reactive than ammonia, especially at lower substrate temperatures (e.g., <900), ammonia radicals and hydrazine compounds can be more effectively used to deposit nitride layers (such as silicon nitride) over a broader range of substrate temperatures.

According to one embodiment, a system is provided herein for processing a substrate, where the system includes a gas activation chamber configured to thermally activate a nitrogen-containing gas. The gas activation chamber may generally include: (a) a housing having an input port coupled to receive the nitrogen-containing gas, (b) a heated gas flow channel configured to heat the nitrogen-containing gas to a temperature between 1200 C and 2000 C to decompose at least a portion of the nitrogen-containing gas into radicals, (c) at least one output port coupled to supply the heated nitrogen-containing gas containing the radicals to the substrate while the substrate is maintained at a temperature less than 900 C, and (d) at least one heating element coupled to the housing for supplying heat to the housing. Heat from the housing may be transferred to the heated gas flow channel to heat the nitrogen-containing gas flowing through the heated gas flow channel. In some embodiments, thermal or resistive heating may be used to heat the housing, and thus the heated gas flow channel, to a temperature, which is sufficient to thermally activate the nitrogen-containing gas supplied to the input port and flowing through the heated gas flow channel.

In some embodiments, the housing may be formed from a carbon material and/or a silicon carbide material. In some embodiments, the at least one heating element may be formed from a carbon material and/or a silicon carbide material.

In some embodiments, the at least one heating element may be embedded within sidewalls of the housing on opposing sides of the heated gas flow channel to thermally heat the housing. In other embodiments, the at least one heating element may be coupled to sidewalls of the housing on opposing sides of the heated gas flow channel to resistively heat the housing.

In some embodiments, the gas activation chamber described herein may be provided within a showerhead included within the system. When included, the showerhead may shield the substrate from thermal radiation emitted from the housing of the gas activation chamber. In some embodiments, the showerhead may be formed from a material having high thermal conductance. In some embodiments, a reflective surface of the showerhead facing the gas activation chamber may reflect the thermal radiation emitted from the housing of the gas activation chamber to shield the substrate.

In some embodiments, the gas activation chamber may be positioned within the system, such that a distance between the at least one output port and the substrate is between 3 mm and 10 mm. In some embodiments, the at least one output port may consist of one output port provided within a lower portion of the housing. In other embodiments, the at least one output port may comprise a plurality of output ports, which are spaced across a lower portion of the housing to distribute the heated nitrogen-containing gas containing the radicals proportionally to a surface area of the substrate to be exposed per unit time. In some embodiments, a width of the at least one output port and a gas flow of the nitrogen-containing gas may be selected to increase a pressure of the nitrogen-containing gas within the heated gas flow channel to improve the heat transfer from the housing to the heated gas flow channel and increase decomposition of the nitrogen-containing gas flowing therein.

In some embodiments, the nitrogen-containing gas supplied to the input port of the gas activation chamber may be ammonia (NH₃), and the radicals supplied to the substrate may comprise one or more of NH₂, N₂H₂, N₂H₃, and N₂H₄. In some embodiments, the heated gas flow channel may be configured to heat the ammonia to: a first temperature between 1600 C and 2000 C to decompose the ammonia and generate predominantly NH₂ and N₂H₂ radicals; and/or a second temperature between 1200 C and 1600 C to decompose the ammonia and generate predominantly N₂H₃ radicals.

According to another embodiment, a method is provided herein for forming a nitride layer on a substrate using an atomic layer deposition (ALD) process. In general, the method may include supplying a precursor gas to the substrate, wherein a temperature of the substrate is less than 900 C. The method may also include supplying heat to a housing comprising a heated gas flow channel, wherein heat from the housing is transferred to the heated gas flow channel to heat a gas stream containing ammonia (NH₃) flowing through the heated gas flow channel, and wherein the gas stream is heated to a temperature between 1200 C and 2000 C to decompose at least a portion of the ammonia into ammonia radicals. The method may also include supplying the heated gas stream containing the ammonia and the ammonia radicals to the substrate to form the nitride layer on the substrate.

In some embodiments, the method step of supplying the precursor gas to the substrate may include exposing the substrate to a silicon-containing precursor gas to deposit a layer of silicon on a surface of the substrate. In such embodiments, the method step of supplying the heated gas stream may include exposing the substrate to the ammonia and the ammonia radicals contained within the heated gas stream to convert the layer of silicon into a silicon nitride layer.

In some embodiments, the method may be used to generate one or more ammonia radicals, such as one or more of NH₂, N₂H₂, N₂H₃, and N₂H₄. In some embodiments, the gas stream may be heated to a temperature between 1600 C and 2000 C to decompose the ammonia and generate predominantly NH₂ and N₂H₂ radicals. In other embodiments, the gas stream may be heated to a temperature between 1200 C and 1600 C to decompose the ammonia and generate predominantly N₂H₃ radicals.

In some embodiments, the method may also include increasing a pressure of the gas stream to improve heat transfer and increase decomposition.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIG. 1 (PRIOR ART) is a top-down view of an atomic layer deposition (ALD) system.

FIG. 2 is a top-down view of one embodiment of a showerhead and a gas activation chamber that may be used in the ALD system shown in FIG. 1 to deliver ammonia and ammonia radicals to the substrate surface.

FIG. 3 is a cross-sectional view through the showerhead and the gas activation chamber shown in FIG. 2 taken along line 2-2.

FIG. 4 is a top-down view of another embodiment of a showerhead and a gas activation chamber that may be used in the ALD system shown in FIG. 1 to deliver ammonia and ammonia radicals to the substrate surface.

FIG. 5 is a cross-sectional view through the showerhead and the gas activation chamber shown in FIG. 4 taken along line 4-4.

FIG. 6 is a top-down view of another embodiment of a showerhead and a gas activation chamber that may be used in the ALD system shown in FIG. 1 to deliver ammonia and ammonia radicals to the substrate surface.

FIG. 7 is a cross-sectional view through the showerhead and the gas activation chamber shown in FIG. 6 taken along line 6-6.

FIG. 8 is a flowchart diagram illustrating an exemplary method utilizing the techniques disclosed herein.

### DETAILED DESCRIPTION OF ILLUSTRATIVE EMBODIMENTS

Systems and methods are provided herein to thermally activate a nitrogen-containing gas at lower activation temperatures (e.g., below 2000 C) than conventional hot-wire heating methods, while more effectively heating larger gas volumes. In the disclosed embodiments, a gas activation chamber is provided within a deposition system for thermally activating a nitrogen-containing gas. In one example, ammonia (NH₃) may be thermally activated within the gas activation chamber to generate ammonia radicals and/or hydrazine compounds before the ammonia, ammonia radicals and/or hydrazine compounds are delivered to the substrate surface. Because ammonia radicals and hydrazine compounds are significantly more reactive than ammonia, especially at lower substrate temperatures (e.g., <900 C), ammonia radicals and hydrazine compounds can be more effectively used to deposit nitride layers (such as silicon nitride) over a broader range of substrate temperatures.

As described in more detail below, the gas activation chamber may generally include: (a) a housing having an input port coupled to receive the nitrogen-containing gas, (b) a heated gas flow channel configured to heat the nitrogen-containing gas to a temperature between 1200 C and 2000 C to decompose at least a portion of the nitrogen-containing gas into radicals, (c) at least one output port coupled to supply the heated nitrogen-containing gas containing the radicals to the substrate, and (d) at least one heating element coupled to the housing for supplying heat to the housing, wherein heat from the housing is transferred to the heated gas flow channel to heat the nitrogen-containing gas flowing through the heated gas flow channel. In some embodiments, thermal or resistive heating may be used to heat the housing of the gas activation chamber to a temperature, which is sufficient to thermally activate the nitrogen-containing gas supplied to the input port and flowing through the heated gas flow channel.

In some embodiments, the nitrogen-containing gas supplied to the input port may be ammonia (NH₃), and the radicals generated within the heated gas flow channel may include one or more of NH₂, N₂H₂ (diazene), N₂H₃, and N₂H₄ (hydrazine). It is recognized, however, that the techniques described herein are not strictly limited to decomposing ammonia and may be used to decompose other nitrogen-containing gases, such as but not limited to, N₂H₄ (hydrazine), MMH (monomethylhydrazine), NH₂OH (hydroxylamine), HNCO (isocyanic acid), etc.

As used herein, “thermally activate” means heating the ammonia (or another nitrogen-containing gas) to a temperature, which is sufficient to “crack” or decompose the ammonia into ammonia radicals (i.e., NₓH_{y}, where x,y=0 to 2). Examples of ammonia radicals include, for example, NH₂, N₂H₂ (diazene), N₂H₃, and N₂H₄ (hydrazine). However, the density of ammonia radicals produced within the gas activation chamber may generally depend on the gas activation temperature. For example, NH₂ and N₂H₂ may be predominantly generated at higher activation temperatures (e.g., 1600 C to 2000 C), while N₂H₃ may be predominantly generated at lower activation temperatures (e.g., 1200 C to 1600 C) and increase in population as the gas temperature drops due to the conversion of NH₂ into N₂H₄. For example, N₂H₄ may form as the gas temperature drops below 1200 C after ejection from the output port.

Compared to conventional hot-wire heating methods, the gas activation chamber described herein is able to thermally activate ammonia and generate ammonia radicals at lower activation temperatures (e.g., 1200 C to 2000 C) than those used in conventional methods (e.g., >2000 C). The gas activation chamber described herein avoids substrate charging by utilizing lower activation temperatures (e.g., <=2000 C). In addition, the gas activation chamber described herein provides more effective heating to larger gas volumes, which increases the density or concentration of ammonia radicals generated within the gas activation chamber and supplied to the substrate surface.

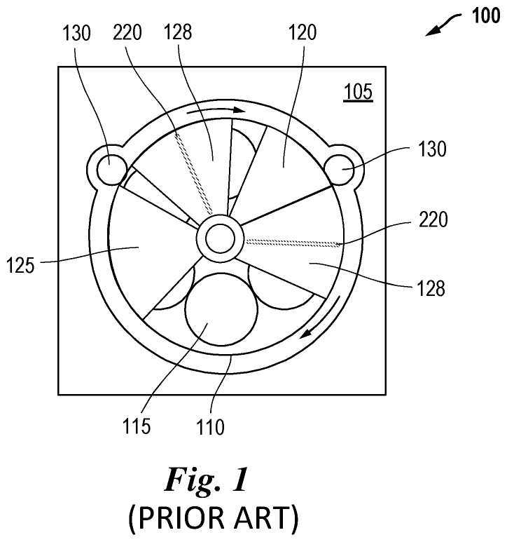

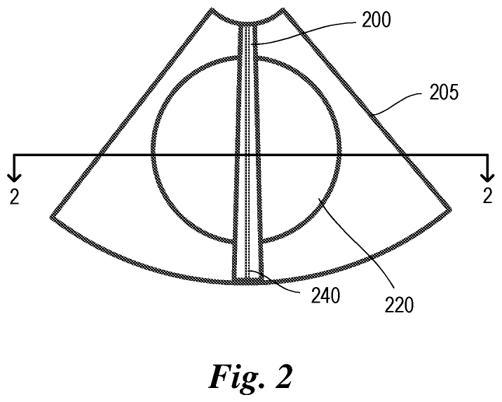

FIGS. 2-7 illustrate various embodiments of a gas activation chamber in accordance with the techniques described herein. In some embodiments, the gas activation chamber shown in FIGS. 2-7 may be incorporated within an atomic layer deposition (ALD) system. For example, the gas activation chamber may be incorporated within a spatial ALD system having a rotating platen, as shown for example in FIG. 1. It is recognized, however, that the gas activation chamber disclosed herein is not strictly limited to the embodiment shown in FIG. 1, and may be incorporated within other spatial ALD systems, other types ALD systems and/or other types of deposition systems. For example, the gas activation chamber may be incorporated within a spatial ALD having a different configuration than shown in FIG. 1, a batch furnace type ALD system or a single substrate ALD system. Alternatively, the gas activation chamber may be incorporated within a chemical vapor deposition (CVD) system or a similar system provided that the radical nitrogen gas species produced from thermal decomposition is mixed with the silicon precursor ex-situ of the gas activation chamber. For example, the gas activation apparatus can be placed within a single wafer CVD chamber opposite to the exhaust port (and to one side of the substrate) resulting in the flow path of ammonia radicals crossing over the substrate. Then a conventional showerhead would provide a source for the silicon precursor whereby the ammonia radicals and silicon precursor would mix over the substrate.

In the embodiments shown in FIGS. 2-7, a gas activation chamber (200, 300, 400) is provided within a showerhead 205 of a spatial atomic layer deposition (ALD) system. The gas activation chamber (200, 300, 400) and the showerhead 205 are arranged above a susceptor 220 provided on a rotating platen 210 of the spatial ALD system. As known in the art, the susceptor 220 may be used to heat the substrate 215 to a desired substrate temperature during one or more steps of an atomic layer deposition (ALD) process.

In one example spatial ALD process, silicon nitride (SiN) layers may be formed by rotating the substrate between a silicon-containing precursor gas (such as, e.g., (DCS)) and a nitrogen-containing gas (such as, e.g., ammonia, NH₃) in rapid succession to build up alternate layers of silicon (Si) and then converting the silicon to silicon nitride (SiN) through exposure to NH₃ until a target thickness is achieved. While exposing the substrate to the precursor gases, the temperature of the substrate 215 may be maintained below the decomposition point of the silicon-containing precursor gas to avoid a CVD component from forming on a structure near the substrate surface. For example, the substrate 215 may be maintained at a temperature less than 900 C, or more preferably at a temperature less than 600 C, when exposing the substrate to the silicon-containing precursor gas and the nitrogen-containing gas. In one example SiN ALD process, the temperature of the substrate 215 may be maintained at approximately 450 C.

When substrate temperatures drop below 600 C, the speed with which the nitrogen-containing gas reacts with the deposited silicon layer decreases, which in turn, decreases the deposition rate of the deposited film layers. Impurities such as hydrogen (H), chlorine (Cl) and/or carbon (C) may also be incorporated into the deposited film layers when substrate temperatures drop below 600 C. By generating and employing radicals, the gas activation chamber (200, 300, 400) shown in FIGS. 2-7 increases the reaction speed of the nitrogen-containing gas, accelerates the deposition rate of the deposited film layers, and more effectively removes impurities for a given process condition.

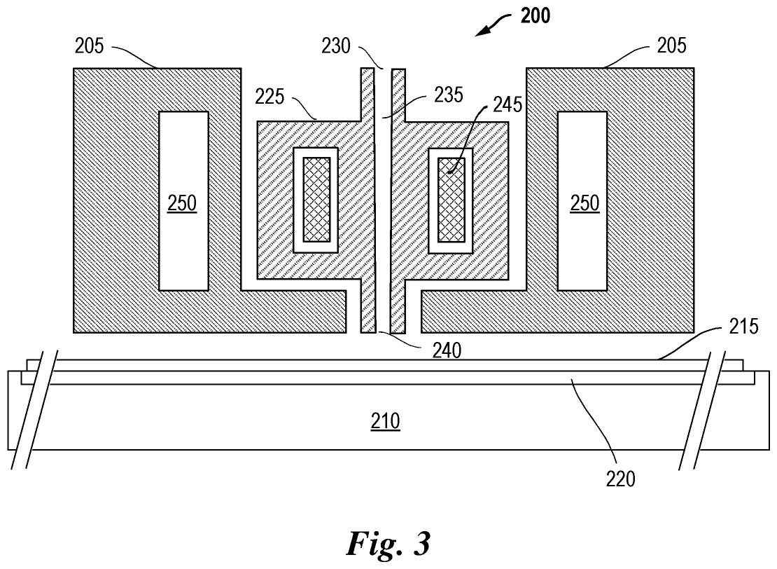

FIGS. 2 and 3 illustrate a first embodiment of a gas activation chamber 200 in accordance with the techniques described herein. As shown in FIGS. 2 and 3, gas activation chamber 200 includes a housing 225 having an input port 230, a heated gas flow channel 235, an output port 240 and at least one heating element 245. The input port 230 is provided within an upper portion of the gas activation chamber 200 and coupled to receive a nitrogen-containing gas, such as but not limited to, ammonia. The heated gas flow channel 235 is configured to heat the nitrogen-containing gas to a temperature sufficient to decompose at least a portion of the nitrogen-containing gas into radicals. The output port 240 is provided within a lower portion of the gas activation chamber 200 and coupled to supply the heated nitrogen-containing gas containing the radicals to the substrate 215. The at least one heating element 245 is embedded within sidewalls of the housing 225 on opposing sides of the heated gas flow channel 235 to thermally heat the housing 225. Heat from the housing 225 is transferred to the heated gas flow channel 235 to heat the nitrogen-containing gas flowing through the heated gas flow channel 235.

The heated gas flow channel 235 provides a primary flow channel for the nitrogen-containing gas, while housing 225 and heating element(s) 245 provide a main source of thermal energy to decompose the nitrogen-containing gas passing through the heated gas flow channel 235. In some embodiments, an ammonia gas stream passing through the heated gas flow channel 235 may be heated to a temperature between approximately 1200 C and 2000 C to “crack” or decompose at least a portion of the ammonia molecules into radicals such as, for example, NH₂, N₂H₂ (diazene), N₂H₃, and N₂H₄ (hydrazine). As noted above, the density of ammonia radicals produced within the gas activation chamber 200 may generally depend on the gas activation temperature. For example, NH₂ and N₂H₂ may be predominantly generated at higher activation temperatures (e.g., 1600 C to 2000 C), while N₂H₃ may be predominantly generated at lower activation temperatures (e.g., 1200 C to 1600 C) and N₂H₄ may form as the gas temperature drops below 1200 C after ejection from the output port 240.

The gas activation chamber 200 shown in FIGS. 2 and 3 avoids substrate charging by utilizing a lower activation temperature (e.g., 1200 C to 2000 C) than the conventional hot-wire heating method (e.g., >2000 C). Even though lower activation temperatures are used, the cracking efficiency of the gas activation chamber 200 is improved over the conventional hot-wire heating method by increasing several key factors, such as gas pressure, time and exposed surface area.

Since the decomposition of ammonia occurs within gas activation chamber 200, the ammonia gas stream must be exposed to a sufficient thermal cycle during passage through the heated gas flow channel 235. In some embodiments, the ammonia gas flow provided to the input port 230 and the width of the output port 240 can be used to control the pressure of the ammonia gas stream flowing through the heated gas flow channel 235. Increasing the gas pressure within the heated gas flow channel 235 improves heat transfer through the ammonia gas stream and aids in decomposition. As the gas pressure increases, the average residence time of the ammonia gas molecules within the heated gas flow channel 235 also increases, thereby increasing thermal exposure. Once a desired gas pressure and residence time are determined, the temperature can be set to optimize the cracking efficiency of the gas activation chamber 200.

An additional factor in the design of the gas activation chamber 200 is the surface area of the heated area exposed to the ammonia. It is beneficial to have a large, heated area to thermally activate the ammonia gas steam and provide optimum conditions for cracking or decomposing the ammonia into radicals. As such, the shape and/or volume of the heated gas flow channel 235 may be a key design consideration in determining an optimum surface area for heating the ammonia gas stream. In some embodiments, for example, a channel width of 0.5 mm, a channel height of 50 mm and an overall length of 340 mm may be used for the heated gas flow channel 235. These dimensions when employed with an ammonia flow in the range of 10 slm to 20 slm provide sufficient flow resistance to increase the pressure and exposure time necessary for effective thermal decomposition of ammonia without excessive residence time in and after passing through the heated gas flow channel 235 yielding the greatest concentration of gas radicals at the substrate's surface.

It is noted that the dimensions provided above for the heated gas flow channel 235 are merely exemplary. Other dimensions may also be appropriate. For example, the dimensions of the heated gas flow channel 235 are dependent on the flow volume of the ammonia. As such, a variety of dimensions may be effective for a broad range of ammonia flows. The ammonia flow is also biased in such a way that the ammonia gas does not spend too much time in the heated gas flow channel 235 and is ejected efficiently before the ammonia gas radicals have time to recombine into N₂Hx species (which are not as reactive as NH₂) before reaching the substrate.

The housing 225 may generally be formed from a material having a high thermal conductance. In some embodiments, the housing 225 may be formed from a carbon material and/or a silicon carbide (SiC) material. In one example embodiment, the housing 225 may be formed from a carbon material, such as graphite, which is then coated with SiC. Graphite is easy to machine, and has a high tolerance to temperature in a non-oxidizing environment. The graphite used to form the housing 225 can be one of several types, such as amorphous graphite or highly ordered pyrolytic graphite. The main differences among these is how thermal conductivity is managed. Since uniform heating of the housing 225 is acceptable, anisotropic thermal conductivity property may not be strictly needed. However, for thermal efficiency purposes, portions of the housing 225 facing the showerhead 205 may in some embodiments be formed from crystalline graphite, which is oriented in such a way that the lowest thermal conducting direction with the greatest area is facing the showerhead 205. This may reduce heat transfer into the showerhead 205 since thermal conduction will slow the rate of outer wall heating, resulting in a lower outer wall temperature, which in turn, reduces the total radiation component to the showerhead 205.

In the embodiment shown in FIGS. 2 and 3, the at least one heating element 245 is embedded within the housing 225 to provide a source of thermal heat to the housing 225, which in turn, provides thermal heat to the ammonia gas stream flowing through the heated gas flow channel 235. In order to heat the ammonia gas stream to the desired temperature range (e.g., 1200 C to 2000 C), the at least one heating element 245 is formed from an electrically conductive material that can sustain temperatures in excess of 1600 C. Like the housing 225, the at least one heating element 245 may be formed from carbon (C), silicon carbide (SiC) or a combination of C and SiC, in some embodiments. However, the design of the at least one heating element 245 may depend on several material physical characteristics, such as electrical conductivity, strength, and thermal expansion. In one preferred embodiment, the at least one heating element 245 may be formed from a carbon material, such as graphite, which is then coated with a thick layer (e.g., 100's of micrometers) of SiC for mechanical strength. The total length of active heating section may depend on the cross section and surface power density of the at least one heating element 245 and can be determined by standard engineering methods.

The gas activation chamber 200 shown in FIGS. 2 and 3 improves upon conventional hot-wire heating methods by thermally activating the greatest amount of ammonia (or another nitrogen-containing gas) at the lowest possible activation temperature (e.g., 1200 C to 2000 C), while preserving as many ammonia radicals as possible before the ammonia radicals are delivered to the substrate surface. The gas activation chamber 200 provides sufficient thermal exposure for the ammonia to “crack” or decompose into ammonia radicals by increasing the pressure of the ammonia gas stream and the residence time of the ammonia gas molecules within the heated gas flow channel 235 at the desired activation temperature.

The lifetime of ammonia radicals is short, especially as the gas temperature begins to decrease as the gas stream exits the housing 225 at the output port 240. As the gas temperature decreases, ammonia radicals and higher order hydrazine compounds begin to recombine. To preserve the highest concentration of ammonia radicals and hydrazine compounds, the gas activation chamber 200 is positioned within the ALD system, so that output port 240 is preferably within 3 mm to 10 mm of the surface of the substrate 215. In one example embodiment, the gas activation chamber 200 may be positioned, such that a 4 mm gap is provided between the output port 240 and the surface of substrate 215.

In some embodiments, ammonia radicals (including, e.g., NH₂, N₂H₂, N₂H₃ and N₂H₄) may be generated within the gas activation chamber 200 by supplying an ammonia gas stream to input port 230 at a flow rate of 10 slm to 20 slm which may result in a peak pressure of up to 70 Torr within the gas activation chamber, and by heating the ammonia gas stream to a temperature of approximately 1200 C to 2000 C. In one particular embodiment, ammonia radicals may be generated by supplying an ammonia gas stream to input port 230 at a flow rate of 10 slm, and by heating the ammonia gas stream to a temperature of approximately 1600 C. In such an embodiment, the amount of ammonia radicals produced within gas activation chamber 200 may be on average about 1% of the input gas concentration (by volume).

However, the peak value of a given radical species output from the gas activation chamber 200 may generally depend on its location, i.e., the distance from the output port 240. In one example, a peak value about 0.6% of NH₂ may occur immediately below the output port 240. This is significant, since NH₂ is approximately 102 to 104 times more reactive than ammonia. For low temperature processing (e.g., substrate temperatures below 600 C), it is expected that NH₂ radicals will be even more effective, as the activation energy of NH₂ radicals is significantly less than that of ammonia (on Si—Cl surfaces). At even lower temperatures (e.g., substrate temperatures below 400 C), ammonia will lose reactivity quickly; however, NH₂ and other ammonia radicals will not lose reactivity and will continue surface reactions.

The primary function of the showerhead 205 is to shield the substrate 215 from thermal energy radiated from housing 225. Although gas activation chamber 200 heats the ammonia gas stream to a temperature over 1200 C, the amount of energy transported by the ammonia gas stream is much less than the amount of energy that could be transmitted via radiation from the housing 225 to the substrate 215. Thus, shielding is an important design concept.

In order to provide effective shielding for the substrate, showerhead 205 is preferably formed from a material such as aluminum, stainless steel, nickel-chromium alloys or other relatively stable and inert metals having a high thermal conductance (e.g., >10 W/(m-K)) and low emissivity (e.g., <0.1). In one example embodiment, showerhead 205 may be formed from aluminum. In addition to having high thermal conductance, aluminum can be polished to provide a highly specular, reflective surface. Since this type of surface has a low emissivity value (˜0.05), it provides excellent reflection of incident radiation.

In some embodiments, one or more surfaces of the showerhead 205 facing the housing 225 may be polished to provide a highly reflective surface that reflects thermal radiation emitted from the housing 225 and shields the substrate 215. This enables the showerhead 205 to provide excellent insulation for the housing 225, thereby limiting energy loss within the housing and blocking almost all thermal radiation from reaching the substrate 215.

In some embodiments, water cooling channels 250 may be provided within the showerhead 205 to further reduce the amount of thermal energy radiated from the housing to the substrate 215. Although used in some embodiments, water cooling channels 250 may not be necessary in all embodiments, since the heat rejection of the showerhead 205 due to radiation is high. There is also some flexibility in the location of the water cooling channels 250, due to the high thermal conductivity of the material (e.g., aluminum) used to form the showerhead 205. For example, instead of embedding water cooling channels 250 within the showerhead 205, as shown in FIG. 3, it may be possible to place the water cooling channels on an external surface of the showerhead 205. Depending on the thermal load, some embodiments may even omit the water cooling channels 250 and rely solely on convention to cool the showerhead 205.

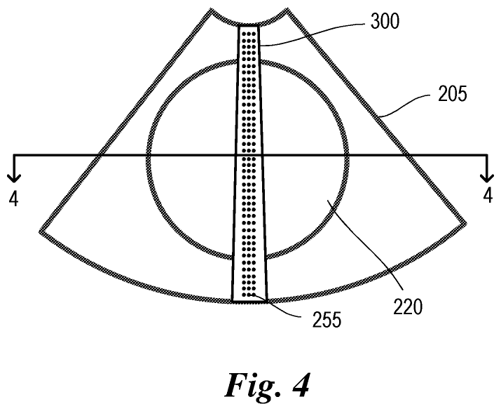

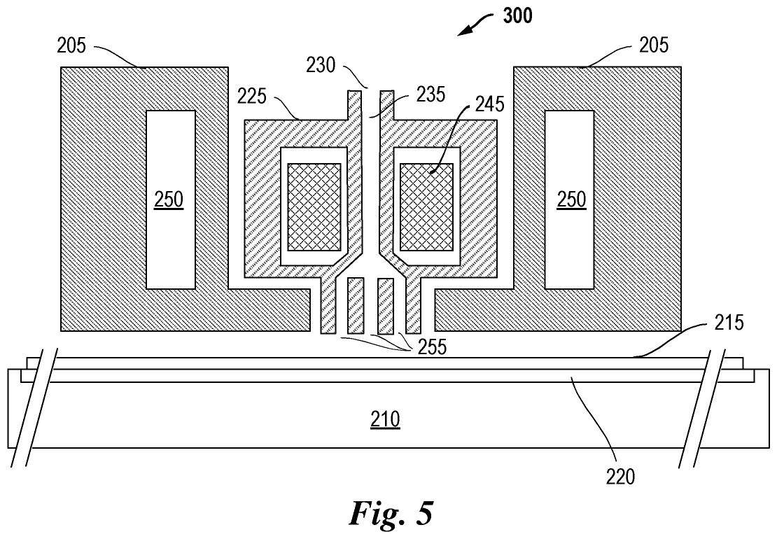

FIGS. 4 and 5 illustrate a second embodiment of a gas activation chamber 300 in accordance with the techniques described herein. The gas activation chamber 300 shown in FIGS. 4 and 5 includes many of the same components shown in FIGS. 2 and 3 and described above. Similar components are designated with identical reference numerals in FIGS. 2-5.

The gas activation chamber 300 shown in FIGS. 4 and 5 differs the gas activation chamber 200 shown in FIGS. 2 and 3, in one respect, by replacing output port 240 with a plurality of output ports 255. In the embodiment shown in FIGS. 4 and 5, the plurality of output ports 255 are spaced across a lower portion of the housing 225 to distribute the ammonia gas and ammonia radicals proportionally to a surface area of the substrate 215 to be exposed per unit time. The dimensions of the housing 225 and/or the at least one heating element 245 may also differ in the embodiment show in FIGS. 4 and 5. Compared to the embodiment shown in FIGS. 2 and 3, for example, the housing 225 may be enlarged to permit a series of spaced holes to provide distribution of the cracked ammonia instead of a single output port 240 or slot. To account for the increase in mass and area, the dimensions of the at least one heating element 245 may change, resulting in a larger cross section of material capable of handling larger electrical currents.

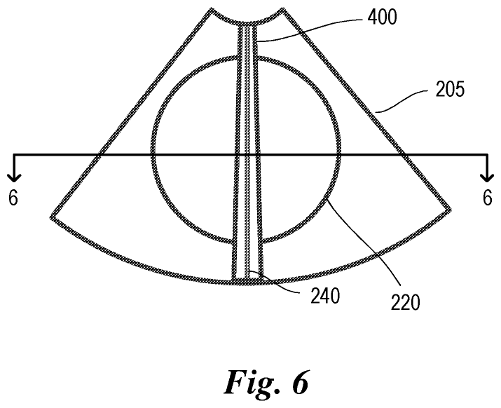

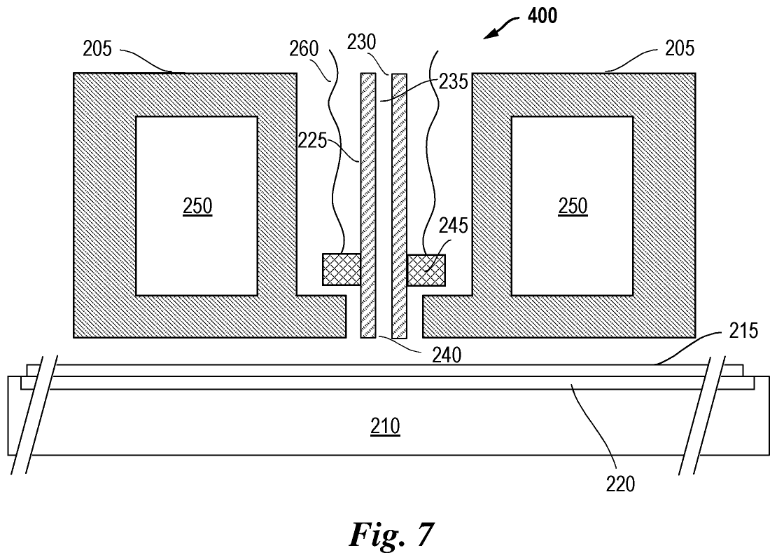

FIGS. 6 and 7 illustrate a third embodiment of a gas activation chamber 400 in accordance with the techniques described herein. The gas activation chamber 400 shown in FIGS. 6 and 7 includes many of the same components shown in FIGS. 2 and 3 and described above. Similar components are designated with identical reference numerals in FIGS. 2, 3, 6 and 7.

The gas activation chamber 400 shown in FIGS. 6 and 7 differs the gas activation chamber 200 shown in FIGS. 2 and 3, in one respect, by using a resistive heating method to heat the housing 225 and the ammonia gas stream flowing through the heated gas flow channel 235. Instead of embedding the heating elements 245 within the housing 225, as shown in FIGS. 2 and 3, for example, the heating elements 245 shown in FIGS. 6 and 7 are coupled to sidewalls of the housing 225 on opposing sides of the heated gas flow channel 235. Electrical leads 260 are coupled to supply current to the heating elements 245 to resistively heat the housing 225.

In some embodiments, heating elements 245 may be omitted and current may be supplied directly to the output port 240 via electrical leads 260. For example, output port 240 may be an injection nozzle formed from electrically conductive material(s), such as carbon, silicon carbide or a combination of carbon and silicon carbide. By machining the injection nozzle to provide a favorable path for the flow of electrical current, localized heat can be produced in the injection nozzle to optimize the cracking efficiency of the gas activation chamber 400. The advantage of such a design is that the injection nozzle can be more compact and the thermal energy needed to “crack” the ammonia can be applied more efficiently, directly to the ammonia, as the ammonia passes through the injection nozzle.

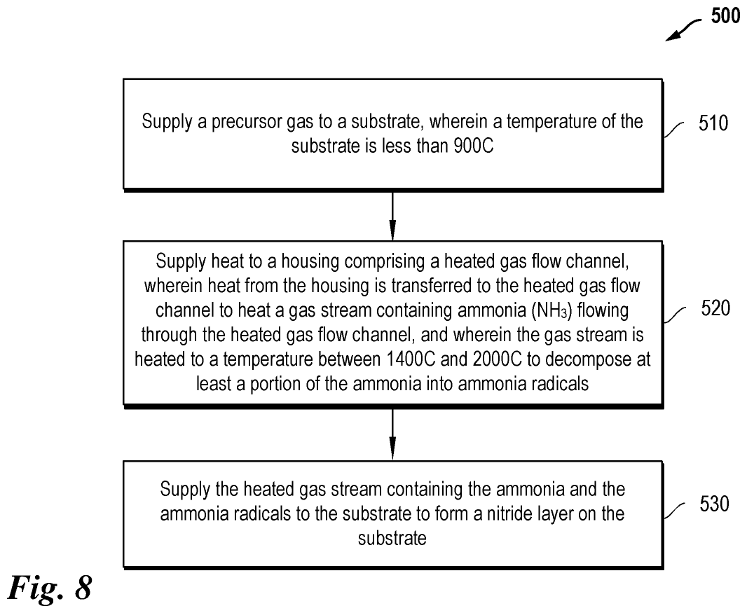

FIG. 8 illustrates one embodiment of an exemplary method that uses the techniques described herein. It will be recognized that the embodiment shown in FIG. 8 is merely exemplary and additional methods may utilize the techniques described herein. Further, additional processing steps may be added to the method shown in FIG. 8 as the steps described are not intended to be exclusive. Moreover, the order of the steps is not limited to the order shown in the figures as different orders may occur and/or various steps may be performed in combination or at the same time.

FIG. 8 illustrates one embodiment method 500 for forming a nitride layer on a substrate using an atomic layer deposition (ALD) process. As shown in FIG. 8, the method 500 may include supplying a precursor gas to the substrate, wherein a temperature of the substrate is less than 900 C in step 510. In step 520, the method 500 may include supplying heat to a housing comprising a heated gas flow channel, wherein heat from the housing is transferred to the heated gas flow channel to heat a gas stream containing ammonia (NH₃) flowing through the heated gas flow channel, and wherein the gas stream is heated to a temperature between 1200 C and 2000 C to decompose at least a portion of the ammonia into ammonia radicals. In step 530, the method 500 may include supplying the heated gas stream containing the ammonia and the ammonia radicals to the substrate to form the nitride layer on the substrate.

Further modifications and alternative embodiments of the inventions will be apparent to those skilled in the art in view of this description. Accordingly, this description is to be construed as illustrative only and is for the purpose of teaching those skilled in the art the manner of carrying out the inventions. It is to be understood that the forms and method of the inventions herein shown and described are to be taken as presently preferred embodiments. Equivalent techniques may be substituted for those illustrated and described herein and certain features of the inventions may be utilized independently of the use of other features, all as would be apparent to one skilled in the art after having the benefit of this description of the inventions.

What is claimed is:

1. A system for processing a substrate, comprising:
a gas activation chamber configured to thermally activate a nitrogen-containing gas, the gas activation chamber comprising
a housing having an input port coupled to receive the nitrogen-containing gas, a heated gas flow channel configured to heat the nitrogen-containing gas to a temperature between 1200° C. and 2000° C. to decompose at least a portion of the nitrogen-containing gas into radicals, and at least one output port coupled to supply the heated nitrogen-containing gas containing the radicals to the substrate while the substrate is maintained at a temperature less than 900° C.; and
at least one heating element coupled to the housing for supplying heat to the housing, wherein heat from the housing is transferred to the heated gas flow channel to heat the nitrogen-containing gas flowing through the heated gas flow channel.

2. The system of claim 1, wherein the housing is formed from a carbon material or a silicon carbide material.

3. The system of claim 2, wherein the at least one heating element is formed from a carbon material or a silicon carbide material.

4. The system of claim 1, wherein the at least one heating element is embedded within sidewalls of the housing on opposing sides of the heated gas flow channel to thermally heat the housing.

5. The system of claim 1, wherein the at least one heating element is coupled to sidewalls of the housing on opposing sides of the heated gas flow channel to resistively heat the housing.

6. The system of claim 1, wherein the gas activation chamber is provided within a showerhead of the system, and wherein the showerhead shields the substrate from thermal radiation emitted from the housing of the gas activation chamber.

7. The system of claim 6, wherein the showerhead is formed from a material having high thermal conductance.

8. The system of claim 6, wherein a reflective surface of the showerhead facing the gas activation chamber reflects the thermal radiation emitted from the housing of the gas activation chamber to shield the substrate.

9. The system of claim 1, wherein the gas activation chamber is positioned within the system, such that a distance between the at least one output port and the substrate is between 3 mm and 10 mm.

10. The system of claim 1, wherein the at least one output port consists of one output port provided within a lower portion of the housing.

11. The system of claim 1, wherein the at least one output port comprises a plurality of output ports, which are spaced across a lower portion of the housing to distribute the heated nitrogen-containing gas containing the radicals proportionally to a surface area of the substrate to be exposed per unit time.

12. The system of claim 1, wherein a width of the at least one output port and a gas flow of the nitrogen-containing gas are selected to increase a pressure of the nitrogen-containing gas within the heated gas flow channel to improve the heat transfer from the housing to the heated gas flow channel and increase decomposition of the nitrogen-containing gas flowing therein.

13. The system of claim 1, wherein the nitrogen-containing gas is ammonia (NH₃), and wherein the radicals comprise one or more of NH₂, N₂H₂, N₂H₃, and N₂H₄.

14. The system of claim 13, wherein the heated gas flow channel is configured to heat the ammonia to:
a first temperature between 1600° C. and 2000° C. to decompose the ammonia and generate predominantly NH₂ and N₂H₂ radicals; and/or
a second temperature between 1200° C. and 1600° C. to decompose the ammonia and generate predominantly N₂H₃ radicals.

15. A method for forming a nitride layer on a substrate using an atomic layer deposition (ALD) process, the method comprising:
supplying a precursor gas to the substrate, wherein a temperature of the substrate is less than 900° C.;
supplying heat to a housing comprising a heated gas flow channel, wherein heat from the housing is transferred to the heated gas flow channel to heat a gas stream containing ammonia (NH₃) flowing through the heated gas flow channel, and wherein the gas stream is heated to a temperature between 1200° C. and 2000° C. to decompose at least a portion of the ammonia into ammonia radicals; and
supplying the heated gas stream containing the ammonia and the ammonia radicals to the substrate to form the nitride layer on the substrate.

16. The method of claim 15, wherein supplying the precursor gas to the substrate comprises exposing the substrate to a silicon-containing precursor gas to deposit a layer of silicon on a surface of the substrate, and wherein supplying the heated gas stream comprises exposing the substrate to the ammonia and the ammonia radicals contained within the heated gas stream to convert the layer of silicon into a silicon nitride layer.

17. The method of claim 15, wherein the ammonia radicals comprise one or more of NH₂, N₂H₂, N₂H₃, and N₂H₄.

18. The method of claim 15, wherein the gas stream is heated to a temperature between 1600° C. and 2000° C. to decompose the ammonia and generate predominantly NH₂ and N₂H₂ radicals.

19. The method of claim 15, wherein the gas stream is heated to a temperature between 1200° C. and 1600° C. to decompose the ammonia and generate predominantly N₂H₃ radicals.

20. The method of claim 15, further comprising increasing a pressure of the gas stream to improve heat transfer and increase decomposition.
